(19) United States
(12) Patent Application Publication
(10) Pub. No.: US 2009/0035898 A1
(43) Pub. Date: Feb. 5, 2009

(54) METHOD OF FABRICATING A LAYER WITH TINY STRUCTURE AND THIN FILM TRANSISTOR COMPRISING THE SAME

(75) Inventor: Chao-An Jong, Hsinchu City (TW)

Correspondence Address: QUINTERO LAW OFFICE, PC, 2210 MAIN STREET, SUITE 200, SANTA MONICA, CA, 90405, US

(73) Assignee: INDUSTRIAL TECHNOLOGY RESEARCH INSTITUTE, HSINCHU (TW)

(21) Appl. No.: 11/874,820

(22) Filed: Oct. 18, 2007

(30) Foreign Application Priority Data
Feb. 5, 2007 (TW) TW96104052

(51) Int. Cl. H01L 21/336; B05D 3/06

(52) U.S. Cl. 438/151; 427/532; 427/553; 427/555; 257/E21.411

(57) ABSTRACT

A method of fabricating a layer with a tiny structure and a thin film transistor comprising the same is disclosed. The method of fabricating the layer with a tiny structure comprises providing a substrate, coating a coating composition on the substrate to form a coating layer, wherein the coating composition comprises nano conductive particles or nano semiconductor particles having functional groups bonded on a surface thereof uniformly dispersed in a solvent, and irradiating the coating layer by an additional energy to break the functional groups, resulting in aggregation of nano conductive particles or nano semiconductor particles to form a tiny structure.

### BACKGROUND OF THE INVENTION

1. Field of the Invention

The invention relates to a method of fabricating a semiconductor device, and in particular to a method of fabricating a semiconductor device comprising organic nano material.

2. Description of the Related Art

Organic nano material is popularly used in fabrication of thin film transistors and various electronic and optoelectronic devices. Compared to conventional thin film transistors, organic thin film transistors utilizing organic semiconductor materials have advantages of a simpler manufacturing process, lower costs and being mass produced. Additionally, the organic thin film transistor is fabricated in a low-temperature process such that a cheap light-weight thin-profile plastic substrate is suitable. Moreover, the organic thin film transistor can function even when the panel (substrate) is wound, facilitating development of flexible electronic products (for example, flexible displays or radio frequency identifications (RFIDs)).

Generally, organic thin film transistors are fabricated by a printing process or a solution process, with small mask numbers and low costs. Conventional printing processes, for example, lithographic printing and relief printing, can achieve high yield and high resolution. However, adjustment of material hydrophilicity is difficult. Similarly, other process techniques, for example, nano imprint, din-pen or micro contact, suffer from lower yield and higher costs.

Thus, given conventional manufacturing techniques, development of a method for fabricating flexible electronic devices (for example, organic thin film transistors) capable of having tiny design patterns, being massed produced, achieving high yields and having lower costs is desirable.

### BRIEF SUMMARY OF THE INVENTION

One embodiment of the invention provides a coating composition comprising nano conductive particles or nano semiconductor particles having functional groups bonded on a surface thereof to prepare a tiny structure, facilitating formation of tiny patterns. The tiny structure is also applied for fabrication of thin film transistors. One embodiment of the invention provides a method of fabricating a layer with tiny structures comprising providing a substrate, coating a coating composition on the substrate to form a coating layer, wherein the coating composition comprises nano conductive particles or nano semiconductor particles having functional groups bonded on a surface thereof uniformly dispersed in a solvent, and irradiating the coating layer by an additional energy to break the functional groups, resulting in aggregation of nano conductive particles or nano semiconductor particles forming a tiny structure.

One embodiment of the invention provides a method of fabricating a thin film transistor comprising providing a substrate, coating a coating composition on the substrate to form a dielectric layer, wherein the coating composition comprises nano conductive particles having functional groups bonded on a surface thereof uniformly dispersed in a solvent, irradiating the dielectric layer by an additional energy to break the functional groups, resulting in aggregation of nano conductive particles to form a tiny conductive structure having two sides, forming an insulation layer overlying the tiny conductive structure, forming a source and a drain on both sides of the tiny conductive structure, and forming a semiconductor layer on the tiny conductive structure, connected to the source and the drain.

One embodiment of the invention provides a method of fabricating a thin film transistor comprising providing a substrate, forming a gate thereon, forming a gate insulation layer overlying the gate, coating a coating composition on the gate insulation layer to form a dielectric layer, wherein the coating composition comprises nano semiconductor particles having functional groups bonded on a surface thereof uniformly dispersed in a solvent, irradiating the dielectric layer by an additional energy to break the functional groups, resulting in aggregation of nano semiconductor particles to form a tiny semiconductor structure having two sides, and forming a source and a drain on both sides of the tiny semiconductor structure, respectively connected to the tiny semiconductor structure.

One embodiment of the invention provides a method of fabricating a thin film transistor comprising providing a substrate, coating a coating composition on the substrate to form a dielectric layer, wherein the coating composition comprises nano semiconductor particles having functional groups bonded on a surface thereof uniformly dispersed in a solvent, irradiating the dielectric layer by an additional energy to break the functional groups, resulting in aggregation of nano semiconductor particles to form a tiny semiconductor structure having two sides, forming a source and a drain on both sides of the tiny semiconductor structure, respectively connected to the tiny semiconductor structure, forming a gate insulation layer on the tiny semiconductor structure, the source and the drain, and forming a gate on the gate insulation layer.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawing, wherein:

FIGS. 1a˜1e are cross-sectional views of a method of fabricating a bottom-gate thin film transistor in an embodiment of the invention.

FIG. 2 is a top view of FIG. 1b.

FIG. 3 is a top view of FIG. 1e.

FIGS. 4a˜4g are cross-sectional views of a method of fabricating a top-gate thin film transistor in an embodiment of the invention.

FIGS. 5a˜5d are cross-sectional views of a method of fabricating a top-gate thin film transistor in an embodiment of the invention.

FIG. 6 is a top view of FIG. 5b.

FIGS. 7a˜7c are cross-sectional views of a method of fabricating a bottom-gate thin film transistor in an embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

One embodiment of the invention provides a coating composition comprising nano conductive particles or nano semiconductor particles having functional groups bonded on a surface thereof to form a coating layer. The functional groups of the nano particles are broken by irradiation of an additional energy, resulting in aggregation of nano particles forming a tiny structure, facilitating formation of tiny patterns. The tiny structure is also applied for fabrication of thin film transistors.

The coating composition comprises the nano conductive particles or nano semiconductor particles having functional groups bonded on the surface thereof uniformly dispersed in a solvent. The coating composition may further comprise an additive to increase solubility and printability. Specifically, the nano conductive particles or nano semiconductor particles are bonded with surfactants or dispersion agents to form the nano conductive particles or nano semiconductor particles having functional groups bonded on the surface thereof. The nano conductive particles may comprise gold, silver, nickel, copper, tungsten or aluminum. The nano semiconductor particles may comprise nickel oxide, cadmium selenium, zinc oxide, stannum oxide or titanium oxide.

The coating composition is coated on a substrate by, for example, spin coating, spray coating, dip coating or printing, to form the coating layer. The nano conductive particles or nano semiconductor particles having functional groups bonded on the surface thereof are uniformly dispersed within the coating layer. The nano conductive particles or nano semiconductor particles are separated, without aggregation, due to formation of the functional groups. When the coating layer is irradiated by an additional energy (for example, linear irradiation), the functional groups bonded with the nano conductive particles or nano semiconductor particles are broken, resulting in aggregation of the nano conductive particles or nano semiconductor particles forming a tiny structure.

The tiny structure provided by the invention is used in all of the semiconductor devices, electronic devices or patterning technologies.

One embodiment of the invention provides a tiny structure to prepare tiny patterns. The tiny structure is also applied for fabrication of thin film transistors.

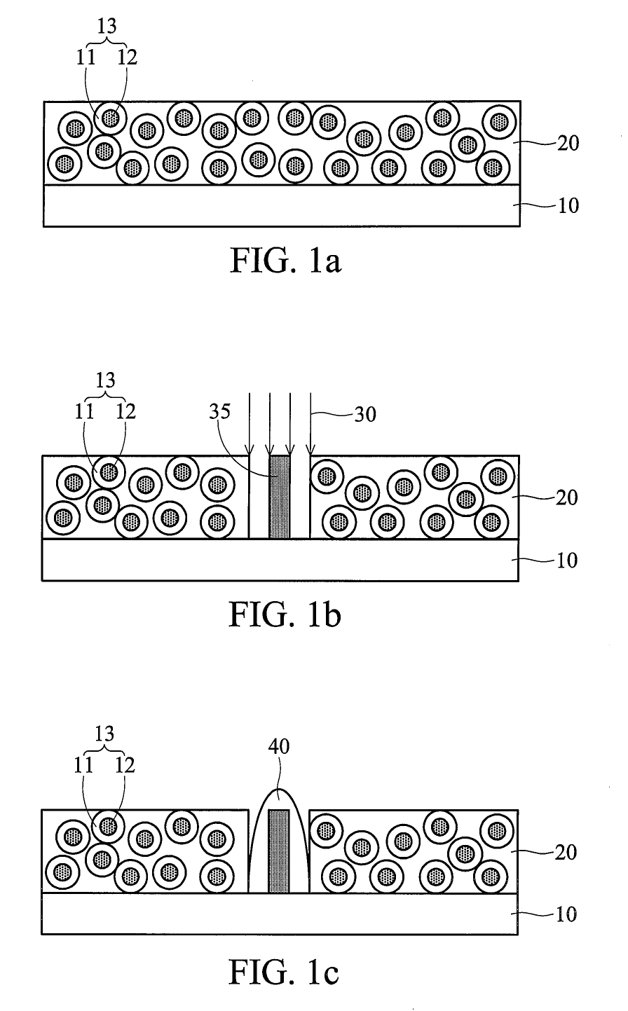

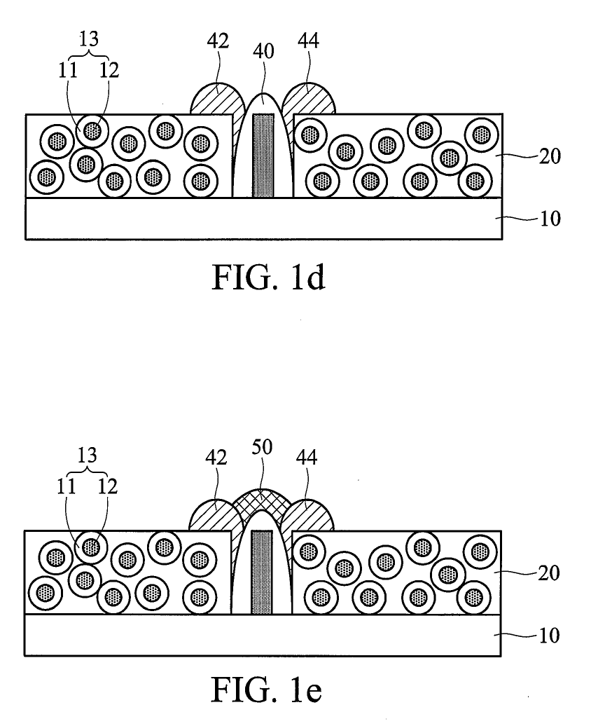

FIGS. 1a˜1e show cross-sectional views of a method of fabricating a bottom-gate thin film transistor in an embodiment of the invention. Referring to FIG. 1a, a substrate 10 is provided. A coating composition is then coated on the substrate 10 to form a dielectric layer 20. Specifically, the coating composition comprises nano conductive particles having functional groups bonded on a surface thereof 13 uniformly dispersed in a solvent. The nano conductive particles having functional groups bonded on the surface thereof 13 are composed of nano conductive particles 12 and functional groups 11. The nano conductive particles 12 may comprise gold, silver, nickel, copper, tungsten or aluminum. The substrate 10 may be a substrate utilized in a semiconductor process, for example, a silicon substrate, flexible substrate or glass substrate.

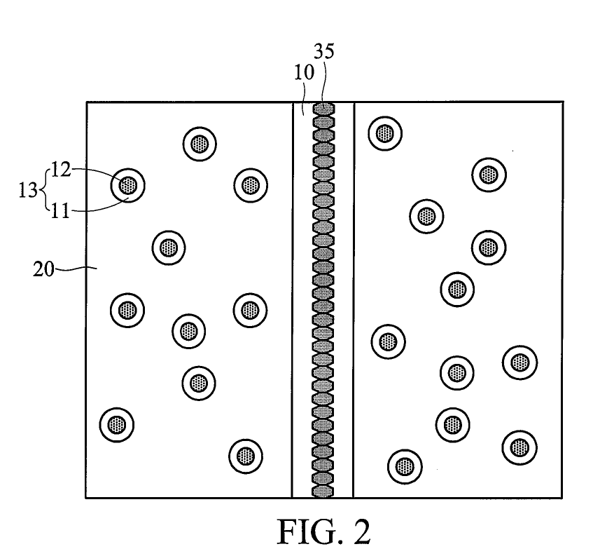

Next, referring to FIG. 1b, the dielectric layer 20 is irradiated by an additional energy 30 to break the functional groups 11, resulting in aggregation of the nano conductive particles 12 to form a tiny linear conductive structure 35 serving as a gate. The additional energy 30 may comprise ultraviolet light, infrared light, laser or microwave. FIG. 2 is a top view of FIG. 1b. In accordance with FIG. 2, the dimension of the tiny linear conductive structure 35 is extremely narrow, for example, less than a micrometer, forming a sub-micro pattern.

Next, referring to FIG. 1c, a patterned gate insulation layer 40 overlying the tiny linear conductive structure 35 serving as a gate is formed. The gate insulation layer 40 may comprise silicon-containing compounds, formed by deposition or coating (for example, SOG material) and then patterned.

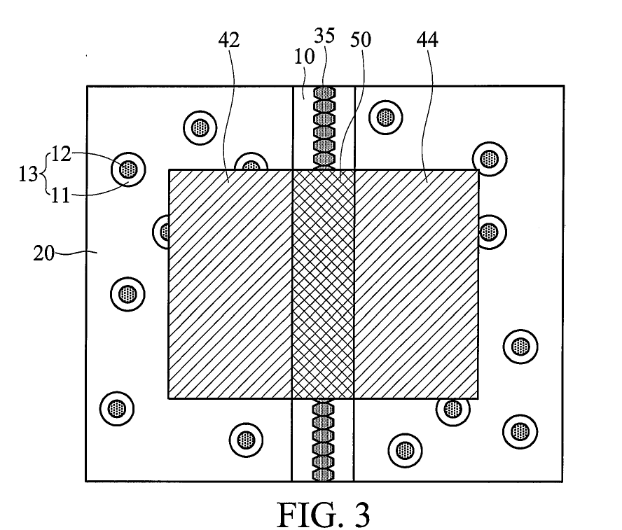

Next, referring to FIG. 1d, a source 42 and a drain 44 are formed on the both sides of the tiny linear conductive structure 35. Referring to FIG. 1e, a semiconductor layer 50 is then formed on the tiny linear conductive structure 35, connected to the source 42 and the drain 44. Thus, the bottom-gate thin film transistor is formed. FIG. 3 is a top view of FIG. 1e. The semiconductor layer 50 and the source/drain 42/44 may be any suitable material, formed by a deposition or solution process.

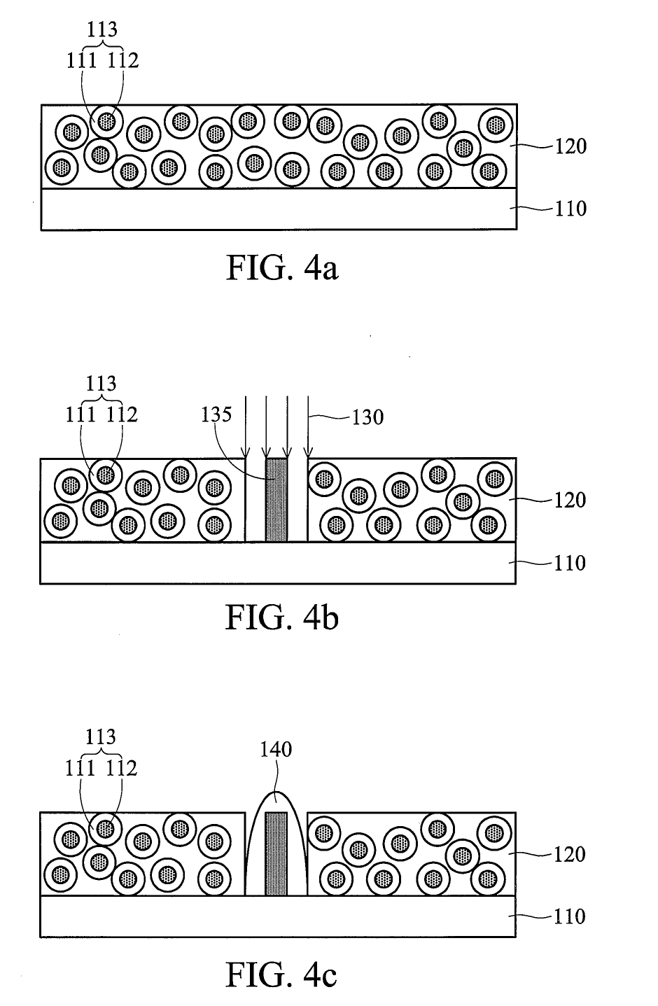

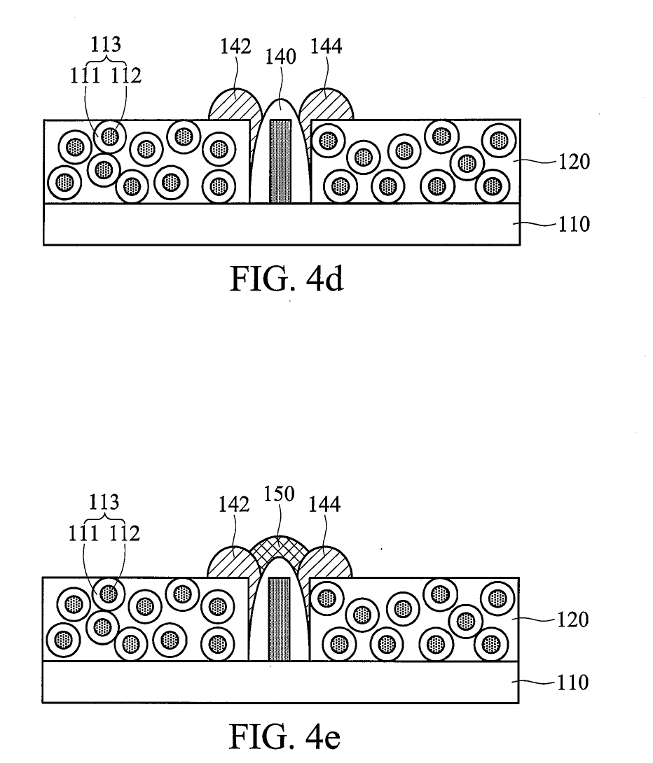

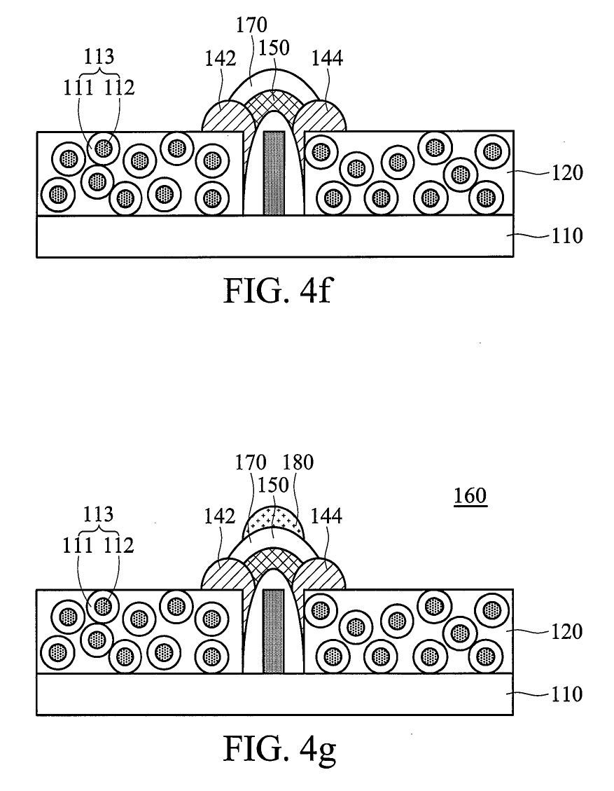

FIGS. 4a˜4g show cross-sectional views of a method of fabricating a top-gate thin film transistor in an embodiment of the invention. Referring to FIG. 4a, a substrate 110 is provided. A coating composition is then coated on the substrate 110 to form a dielectric layer 120. Specifically, the coating composition comprises nano conductive particles having functional groups bonded on a surface thereof 113 uniformly dispersed in a solvent. The nano conductive particles having functional groups bonded on the surface thereof 113 are composed of nano conductive particles 112 and functional groups 111. The nano conductive particles 112 may comprise gold, silver, nickel, copper, tungsten or aluminum. The substrate 110 may be a substrate utilized in a semiconductor process, for example, a silicon substrate, flexible substrate or glass substrate.

Next, referring to FIG. 4b, the dielectric layer 120 is irradiated by an additional energy 130 to break the functional groups 111, resulting in aggregation of the nano conductive particles 112 to form a tiny linear conductive structure 135 serving as a gate. The additional energy 130 may comprise ultraviolet light, infrared light, laser or microwave. The dimension of the tiny linear conductive structure 135 is extremely narrow, for example, less than a micrometer, forming a sub-micro pattern.

Next, referring to FIG. 4c, a patterned gate insulation layer 140 overlying the tiny linear conductive structure 135 serving as a gate is formed. The gate insulation layer 140 may comprise silicon-containing compounds, formed by deposition or coating (for example, SOG material) and then patterned.

Next, referring to FIG. 4d, a source 142 and a drain 144 are formed on the both sides of the tiny linear conductive structure 135. Referring to FIG. 4e, a semiconductor layer 150 is then formed on the tiny linear conductive structure 135, connected to the source 142 and the drain 144. The semiconductor layer 150 and the source/drain 142/144 may be any suitable material, formed by a deposition or solution process.

Next, referring to FIG. 4f, a gate insulation layer 170 is formed on the semiconductor layer 150. The gate insulation layer 170 may comprise silicon-containing compounds, formed by deposition or coating and then patterned.

Finally, referring to FIG. 4g, a gate 180 is formed on the gate insulation layer 170. Thus, the top-gate thin film transistor 160 is formed. The gate 180 may comprise aluminum, tungsten, molybdenum, titanium nitride, or titanium tungsten.

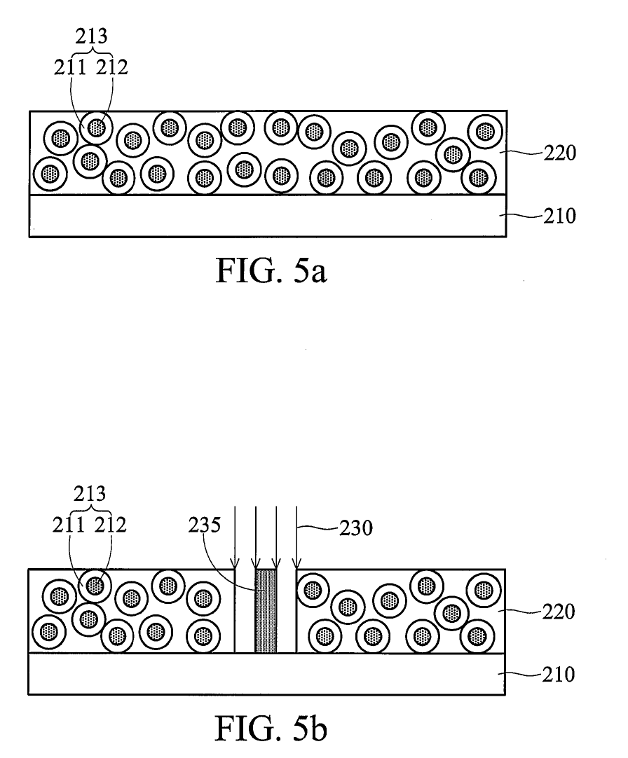

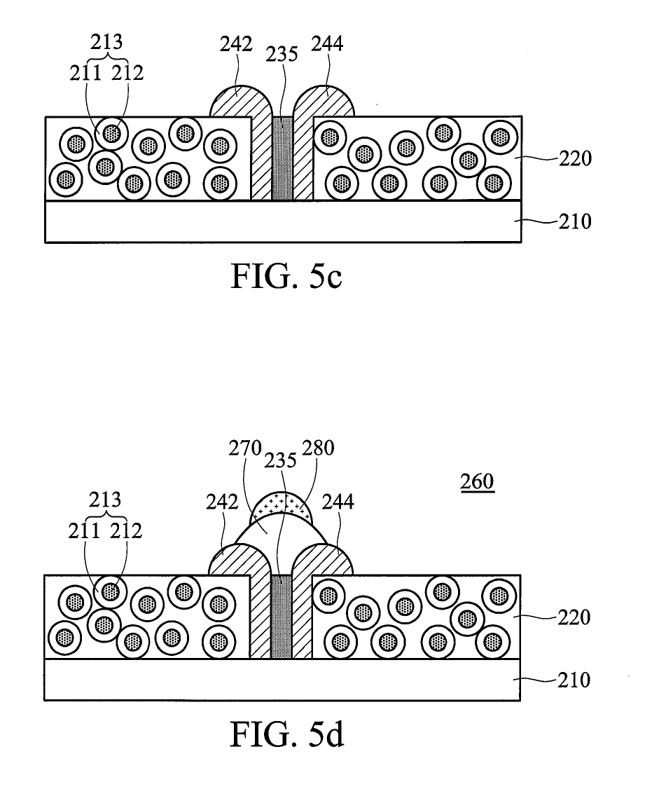

FIGS. 5a˜5d show cross-sectional views of a method of fabricating a top-gate thin film transistor in an embodiment of the invention. Referring to FIG. 5a, a substrate 210 is provided. A coating composition is then coated on the substrate 210 to form a dielectric layer 220. Specifically, the coating composition comprises nano semiconductor particles having functional groups bonded on a surface thereof 213 uniformly dispersed in a solvent. The nano semiconductor particles having functional groups bonded on the surface thereof 213 are composed of nano semiconductor particles 212 and functional groups 211. The nano semiconductor particles 212 may comprise nickel oxide, cadmium selenium, zinc oxide, stannum oxide or titanium oxide. The substrate 210 may be a substrate utilized in a semiconductor process, for example, a silicon substrate, flexible substrate or glass substrate.

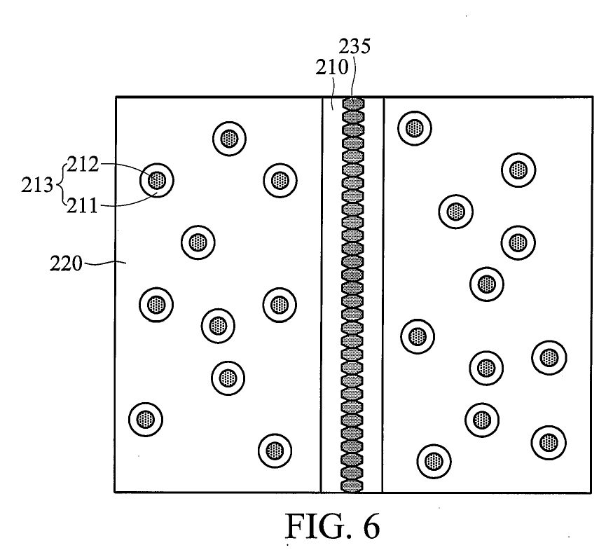

Next, referring to FIG. 5b, the dielectric layer 220 is irradiated by an additional energy 230 to break the functional groups 211, resulting in aggregation of the nano semiconductor particles 212 to form a tiny linear semiconductor structure 235. The additional energy 230 may comprise ultraviolet light, infrared light, laser or microwave. FIG. 6 is a top view of FIG. 5b. In accordance with FIG. 6, the dimension of the tiny linear semiconductor structure 235 is extremely narrow, for example, less than a micrometer, forming a sub-micro pattern.

Next, referring to FIG. 5c, the hydrophilicity of the surface of the dielectric layer 220 is adjusted by a chemical reaction process (for example, plasma process or solvent treatment process) to form two regions with different surface energies. A source 242 and a drain 244 are then formed on both sides of the tiny linear semiconductor structure 235.

Next, referring to FIG. 5d, a gate insulation layer 270 is formed on the tiny linear semiconductor structure 235, the source 242 and the drain 244. A gate 280 is then formed on the gate insulation layer 270. Thus, the top-gate thin film transistor 260 is formed. The gate insulation layer 270 may comprise silicon-containing compounds, formed by deposition or coating and then patterning. The gate 280 may comprise aluminum, tungsten, molybdenum, titanium nitride, or titanium tungsten.

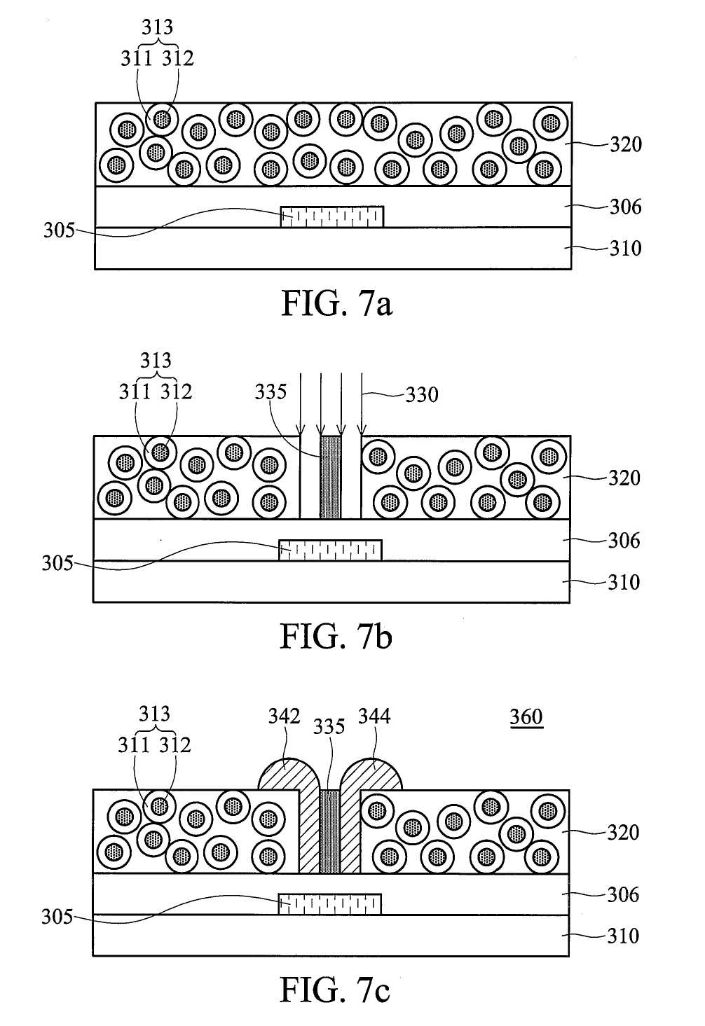

FIGS. 7a˜7c show cross-sectional views of a method of fabricating a bottom-gate thin film transistor in an embodiment of the invention. Referring to FIG. 7a, a substrate 310 is provided. A gate 305 and a gate insulation layer 306 are formed on the substrate 310. The gate 305 may comprise aluminum, tungsten, molybdenum, titanium nitride, or titanium tungsten. The gate insulation layer 306 may comprise silicon-containing compounds, formed by deposition or coating and then patterned. A coating composition is then coated on the gate insulation layer 306 to form a dielectric layer 320. Specifically, the coating composition comprises nano semiconductor particles having functional groups bonded on a surface thereof 313 uniformly dispersed in a solvent. The nano semiconductor particles having functional groups bonded on the surface thereof 313 are composed of nano semiconductor particles 312 and functional groups 311. The nano semiconductor particles 312 may comprise nickel oxide, cadmium selenium, zinc oxide, stannum oxide or titanium oxide. The substrate 310 may be a substrate utilized in a semiconductor process, for example, a silicon substrate, flexible substrate or glass substrate.

Next, referring to FIG. 7b, the dielectric layer 320 is irradiated by an additional energy 330 to break the functional groups 311, resulting in aggregation of the nano semiconductor particles 312 to form a tiny linear semiconductor structure 335. The additional energy 330 may comprise ultraviolet light, infrared light, laser or microwave. FIG. 2 is a top view of FIG. 7b. In accordance with FIG. 2, the dimension of the tiny linear semiconductor structure 335 is extremely narrow, for example, less than a micrometer, forming a sub-micro pattern.

Next, referring to FIG. 7c, a source 342 and a drain 344 are formed on both sides of the tiny linear semiconductor structure 335. Thus, the bottom-gate thin film transistor is formed. The source/drain 342/344 may be any suitable material, formed by a deposition or solution process.

One embodiment of the invention provides a coating composition comprising nano conductive particles or nano semiconductor particles having functional groups bonded on a surface thereof to form a coating layer. The functional groups of the nano particles are broken by irradiation of an additional energy, resulting in aggregation of nano particles to form a tiny structure, facilitating formation of tiny patterns. The tiny structure is also applied for fabrication of thin film transistors. The invention meets the previously set requirements for fabricating organic semiconductor devices given the ability of having a simpler process, of being able to form tiny design patterns, for mass production, for achieving high yields and for having lower costs.

Compared to the conventional methods utilized in fabrication of flexible/organic electronics, for example, a lithography method or e-beam with high cost, dip-pen, nano-imprint, and micro-contact with low throughput and poor uniformity, unsuitable for mass production. Someone demonstrates the possibility of scaling down is helpful in device performance, but some issues exist in these methods. The invention provides a new and easy way to solve the scaling problem and provides a possible process to achieve it.

The invention provides a low cost (without vacuum environment), easily to form a nano-scale tiny structure, under lithography resolution. The nano materials used here for forming conductive lines or semiconductor lines, are completely fulfilled the requirement for scaling down the critical dimension in order to get a high speed/performance TFT operation. The method of forming a TFT can be used in all of the semiconductor/electronic devices which need TFT, especially in flexible, printed, low-temperature process, high throughput, and suitable performance flexible electronics.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method of fabricating a layer with a tiny structure, comprising:
providing a substrate;
coating a coating composition on the substrate to form a coating layer, wherein the coating composition comprises nano conductive particles or nano semiconductor particles having functional groups bonded on a surface thereof uniformly dispersed in a solvent; and
irradiating the coating layer by an additional energy to break the functional groups, resulting in aggregation of nano conductive particles or nano semiconductor particles to form a tiny structure.

2. The method of fabricating a layer with tiny structure as claimed in claim 1, wherein the nano conductive particles or nano semiconductor particles are bonded with surfactants or dispersion agents to form the nano conductive particles or nano semiconductor particles having functional groups bonded on the surface thereof.

3. The method of fabricating a layer with tiny structure as claimed in claim 2, wherein the nano conductive particles comprise gold, silver, nickel, copper, tungsten or aluminum.

4. The method of fabricating a layer with tiny structure as claimed in claim 2, wherein the nano semiconductor particles comprise nickel oxide, cadmium selenium, zinc oxide, stannum oxide or titanium oxide.

5. The method of fabricating a layer with tiny structure as claimed in claim 1, wherein the additional energy comprises ultraviolet light, infrared light, laser or microwave.

6. A method of fabricating a thin film transistor, comprising:
providing a substrate;
coating a coating composition on the substrate to form a dielectric layer, wherein the coating composition comprises nano conductive particles having functional groups bonded on a surface thereof uniformly dispersed in a solvent;
irradiating the dielectric layer by an additional energy to break the functional groups, resulting in aggregation of nano conductive particles to form a tiny conductive structure having two sides;
forming an insulation layer overlying the tiny conductive structure;
forming a source and a drain on both sides of the tiny conductive structure; and
forming a semiconductor layer on the tiny conductive structure, connected to the source and the drain.

7. The method of fabricating a thin film transistor as claimed in claim 6, wherein the nano conductive particles are bonded with surfactants or dispersion agents to form the nano conductive particles having functional groups bonded on the surface thereof.

8. The method of fabricating a thin film transistor as claimed in claim 6, wherein the nano conductive particles comprise gold, silver, nickel, copper, tungsten or aluminum.

9. The method of fabricating a thin film transistor as claimed in claim 6, wherein the tiny conductive structure is a gate.

10. The method of fabricating a thin film transistor as claimed in claim 9, wherein the insulation layer is a gate insulation layer.

11. The method of fabricating a thin film transistor as claimed in claim 6, further comprising:
forming a gate insulation layer on the semiconductor layer; and
forming a gate on the gate insulation layer.

12. The method of fabricating a thin film transistor as claimed in claim 6, wherein the additional energy comprises ultraviolet light, infrared light, laser or microwave.

13. A method of fabricating a thin film transistor, comprising:
providing a substrate;
forming a gate thereon;
forming a gate insulation layer overlying the gate;
coating a coating composition on the gate insulation layer to form a dielectric layer having a surface, wherein the coating composition comprises nano semiconductor particles having functional groups bonded on a surface thereof uniformly dispersed in a solvent;
irradiating the dielectric layer by an additional energy to break the functional groups, resulting in aggregation of nano semiconductor particles to form a tiny semiconductor structure having two sides; and
forming a source and a drain on both sides of the tiny semiconductor structure, respectively connected to the tiny semiconductor structure.

14. The method of fabricating a thin film transistor as claimed in claim 13, before forming the source and the drain, further comprising adjusting hydrophilicity of the surface of the dielectric layer by a chemical reaction process.

15. The method of fabricating a thin film transistor as claimed in claim 13, wherein the nano semiconductor particles are bonded with surfactants or dispersion agents to form the nano semiconductor particles having functional groups bonded on the surface thereof.

16. The method of fabricating a thin film transistor as claimed in claim 13, wherein the nano semiconductor particles comprise nickel oxide, cadmium selenium, zinc oxide, stannum oxide or titanium oxide.

17. The method of fabricating a thin film transistor as claimed in claim 13, wherein the additional energy comprises ultraviolet light, infrared light, laser or microwave.

18. A method of fabricating a thin film transistor, comprising:
providing a substrate;
coating a coating composition on the substrate to form a dielectric layer having a surface, wherein the coating composition comprises nano semiconductor particles having functional groups bonded on a surface thereof uniformly dispersed in a solvent;
irradiating the dielectric layer by an additional energy to break the functional groups, resulting in aggregation of nano semiconductor particles to form a tiny semiconductor structure having two sides;
forming a source and a drain on both sides of the tiny semiconductor structure, respectively connected to the tiny semiconductor structure;
forming a gate insulation layer on the tiny semiconductor structure, the source and the drain; and
forming a gate on the gate insulation layer.

19. The method of fabricating a thin film transistor as claimed in claim 18, before forming the source and the drain, further comprising adjusting hydrophilicity of the surface of the dielectric layer by a chemical reaction process.

20. The method of fabricating a thin film transistor as claimed in claim 18, wherein the nano semiconductor particles are bonded with surfactants or dispersion agents to form the nano semiconductor particles having functional groups bonded on the surface thereof.

21. The method of fabricating a thin film transistor as claimed in claim 18, wherein the nano semiconductor particles comprise nickel oxide, cadmium selenium, zinc oxide, stannum oxide or titanium oxide.

22. The method of fabricating a thin film transistor as claimed in claim 18, wherein the additional energy comprises ultraviolet light, infrared light, laser or microwave.
